(19) United States
(12) Patent Application Publication
(10) Pub. No.: US 2022/0223480 A1
(43) Pub. Date: Jul. 14, 2022

(54) WAFER MEASUREMENT METHOD AND APPARATUS, MEDIUM, AND ELECTRONIC DEVICE

(71) Applicant: CHANGXIN MEMORY TECHNOLOGIES, INC., Hefei City (CN)

(72) Inventor: He ZHU, Hefei (CN)

(21) Appl. No.: 17/502,135

(22) Filed: Oct. 15, 2021

Related U.S. Application Data
(63) Continuation of application No. PCT/CN2021/110374, filed on Aug. 3, 2021.

(30) Foreign Application Priority Data
Jan. 14, 2021 (CN) 202110047543.9

(51) Int. Cl. H01L 21/66; G01N 21/95

(52) U.S. Cl. CPC H01L 22/12; G01N 21/9501

(57) ABSTRACT

A wafer measurement method and apparatus, a medium, and an electronic device are provided. The measurement method includes: acquiring a wafer measurement region image; identifying a characteristic marker in the wafer measurement region image; determining an actual position of the characteristic marker in the wafer measurement region image; determining a deviation amount of the characteristic marker according to the actual position of the characteristic marker and a standard position of the characteristic marker; and determining a deviation amount of a measurement point in the wafer measurement region image according to the deviation amount of the characteristic marker.

### CROSS-REFERENCE TO RELATED APPLICATION

This is a continuation application of International Patent Application No. PCT/CN2021/110374, filed on Aug. 3, 2021, which claims priority to Chinese Patent Application No. 202110047543.9, entitled “WAFER MEASUREMENT METHOD AND APPARATUS, MEDIUM, AND ELECTRONIC DEVICE”, filed with the China National Intellectual Property Administration on Jan. 14, 2021. The disclosures of International Patent Application No. PCT/CN2021/110374 and Chinese Patent Application No. 202110047543.9 are hereby incorporated by reference in their entireties.

### TECHNICAL FIELD

The disclosure relates to the field of semiconductor technologies, and specifically, to a wafer measurement method and apparatus, a computer-readable storage medium, and an electronic device.

### BACKGROUND

Semiconductor factories generally are faced with the problems of numerous manufacturing processes and complex processes. To ensure the quality of a wafer, parameters such as critical sizes of the wafer need to be measured to detect in time whether there is an anomaly in a production line. The measurement of a wafer is highly significant for keeping a manufacturing process stable and reducing a production cost. Most measuring machines need to perform fixed-point measurement on a wafer. A deviation of a measurement point may cause an increase in the workload of a machine, which affects a normal manufacturing process and further causes a reduction in product yield.

It needs to be noted that the information disclosed in the foregoing Background part is only used for better understanding of the background of the disclosure, and therefore may include information that does not constitute the prior art known to a person of ordinary skill in the art.

### SUMMARY

An objective of the embodiments of the disclosure is to provide a wafer measurement method and apparatus, a computer-readable storage medium, and an electronic device.

Other features and advantages of the disclosure will become apparent through the following detailed description or are acquired through the practice of the disclosure.

According to a first aspect of the embodiments of the disclosure, there is provided a wafer measurement method. The method is applicable to a patterned wafer, and includes:

acquiring a wafer measurement region image;

identifying a characteristic marker in the wafer measurement region image;

determining an actual position of the characteristic marker in the wafer measurement region image;

determining a deviation amount of the characteristic marker according to the actual position of the characteristic marker and a standard position of the characteristic marker; and

determining a deviation amount of a measurement point in the wafer measurement region image according to the deviation amount of the characteristic marker.

According to a second aspect of the embodiments of the disclosure, there is provided a wafer measurement apparatus. The wafer measurement apparatus includes:

an acquiring module, configured to acquire a wafer measurement region image;

an identification module, configured to identify a characteristic marker in the wafer measurement region image;

a determination module, configured to determine an actual position of the characteristic marker in the wafer measurement region image; and

an analysis module, configured to determine a deviation amount of the characteristic marker according to the actual position of the characteristic marker and a standard position of the characteristic marker, and determine a deviation amount of a measurement point in the wafer measurement region image according to the deviation amount of the characteristic marker.

According to a third aspect of the embodiments of the disclosure, there is provided an electronic device. The electronic device includes:

one or more processors; and

a storage apparatus, configured to store one or more programs, where the one or more programs, when executed by the one or more processors, cause the one or more processors to implement any one of the foregoing methods.

According to a fourth aspect of the embodiments of the disclosure, there is provided a computer-readable storage medium. The computer-readable storage medium stores a computer program, which implements any one of the foregoing methods when being executed by a processor.

It should be understood that the foregoing general description and the following detailed description are only exemplary and explanatory, and cannot limit the disclosure.

### BRIEF DESCRIPTION OF THE DRAWINGS

The accompanying drawings are incorporated in the specification and constitute a part of the specification, show embodiments conforming to the disclosure, and are used together with the specification to explain the principle of the disclosure. Apparently, the accompanying drawings in the following description show only some embodiments of the disclosure, and a person of ordinary skill in the art may still derive other drawings from these accompanying drawings without creative efforts. In the accompanying drawings:

FIG. 1 schematically illustrates a wafer measurement method according to an exemplary embodiment of the disclosure;

FIG. 2 is a schematic diagram of a wafer measurement region image according to an embodiment of the disclosure;

FIG. 3 is a schematic diagram of a characteristic marker according to an embodiment of the disclosure;

FIG. 4 is a schematic diagram of a wafer measurement region image according to an embodiment of the disclosure;

FIG. 5 is a schematic diagram of a wafer measurement region image according to an embodiment of the disclosure;

FIG. 6 is a schematic flowchart of wafer measurement according to an embodiment of the disclosure;

FIG. 7 illustrates a wafer measurement apparatus according to an embodiment of the disclosure; and

FIG. 8 illustrates a computer system of an electronic device according to an embodiment of the disclosure.

### DETAILED DESCRIPTION

Now exemplary embodiments will be described more fully with reference to the accompanying drawings. However, the exemplary embodiments can be implemented in various ways and shall not be construed as being limited to the examples set forth herein; rather, these embodiments are provided to make the disclosure more comprehensive and complete, and fully convey the concept of the exemplary embodiments to those skilled in the art. Like reference numerals through the drawings denote the same or similar structures, and thus their detailed description will be omitted.

Although relative terms such as “upper” and “lower” are used in the specification to describe the relative relationship of one component with respect to another component as shown in the figures, these terms are used in this specification only for convenience, for example, based on the exemplary directions as shown in the figures. It is to be understood that if the modules as shown in the figures is turned upside down, the described “upper” component will become a “lower” component. Other relative terms such as “high”, “low”, “top”, “bottom”, “left”, and “right” also have similar meanings. When a structure is “on” another structure, it may mean that the structure is integrally formed on the another structure, or that the structure is “directly” provided on the another structure, or that the structure is “indirectly” provided on the another structure via still another structure.

The terms “a”, “an”, and “the” are used to indicate the presence of one or more elements/components/etc. The terms “include” and “have” are used to indicate the meaning including an opening inclusion and indicate that there may be other elements/components/etc. in addition to the listed elements/components/etc.

Semiconductor factories generally are faced with the problems of numerous manufacturing processes and complex processes. To ensure the quality of a wafer, parameters such as critical sizes of the wafer need to be measured to detect in time whether there is an anomaly in a production line. The measurement of a wafer is highly significant for keeping a manufacturing process stable and reducing a production cost. Most measuring machines need to perform fixed-point measurement on a wafer. A deviation of a measurement point may cause an increase in the workload of a machine, which affects a normal manufacturing process and further causes a reduction in product yield.

To resolve the foregoing problem, the disclosure provides a wafer measurement method, which is used for determining whether a measurement point in a wafer deviates, thereby improving the accuracy of wafer measurement.

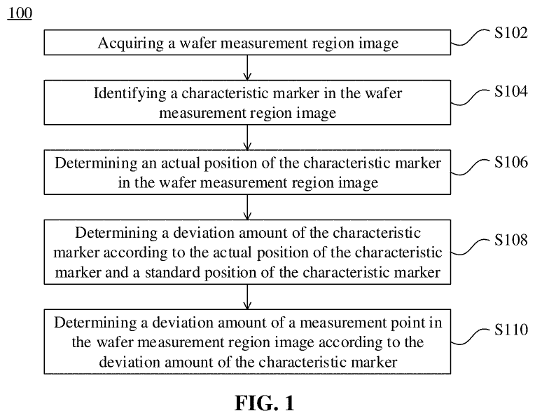

FIG. 1 schematically illustrates a wafer measurement method according to an exemplary embodiment of the disclosure. The method provided in the embodiments of the disclosure may be performed by any electronic device having a computer processing capability, for example, a terminal device and/or a server. Referring to FIG. 1, the wafer measurement method is applicable to a patterned wafer, and may include the following operations.

In S102, a wafer measurement region image is acquired.

In S104, a characteristic marker in the wafer measurement region image is identified.

In S106, an actual position of the characteristic marker in the wafer measurement region image is determined.

In S108, a deviation amount of the characteristic marker is determined according to the actual position of the characteristic marker and a standard position of the characteristic marker.

In S110, a deviation amount of a measurement point in the wafer measurement region image is determined according to the deviation amount of the characteristic marker.

The patterned wafer in the disclosure is a wafer which is obtained after processes such as exposure, development and etching.

In the technical solution of the embodiments of the disclosure, since the relative position between the characteristic marker and the measurement point is fixed, the deviation amount of the measurement point in the wafer measurement region image is determined according to a deviation amount of the actual position of the characteristic marker from the standard position of the characteristic marker, so that the measurement of the measurement point in the wafer can be implemented.

In S102, the wafer measurement region image is acquired.

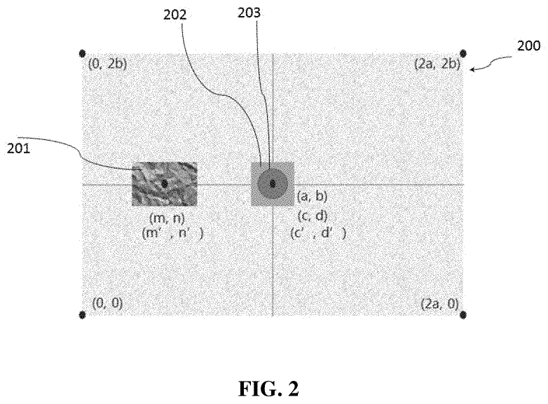

FIG. 2 is a schematic diagram of a wafer measurement region image 200 according to an embodiment of the disclosure. Referring to FIG. 2, a size of the image 200 is fixed. It is defined that the coordinate (0, 0) is the lower left corner of the image 200, (a, b) is the center of the image 200, and (a, b) is always the center of an actual measurement point of a machine. It is defined that the coordinate of a standard central point of a characteristic marker 201 in the image 200 relative to the origin is (m, n), and the coordinate of the central point of the characteristic marker 201 in an actual measurement result of the machine is marked as (m′, n′). It is defined that the coordinate of a standard central point of a measurement point 202 relative to the origin in the image 200 is (c, d) and the coordinate of the central point of the actual measurement point of the machine is marked as (c′, d′).

In S104, the characteristic marker in the wafer measurement region image is identified.

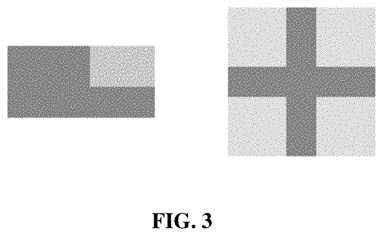

Referring to FIG. 2, in S104, the characteristic marker 201 in the wafer measurement region image 200 is identified. In an embodiment, a feature, corresponding to the characteristic marker 201, in the wafer measurement region image 200 is unique. In an embodiment, the characteristic marker in the wafer measurement region image is identified according to a standard characteristic marker, corresponding to the characteristic marker, in a layout. A position of the standard characteristic marker is the standard position of the characteristic marker. In an actual operation, the wafer measurement region image 200 may be matched against the standard characteristic marker corresponding to the characteristic marker in the layout, to obtain the characteristic marker 201. In some embodiments, the characteristic marker may be any easily recognizable special pattern with a clear edge in the image, or has a clear chromatic aberration from another similar pattern in a measurement image. If a measurement point or a combination of a plurality of measurement points is relatively special and easily recognizable, the measurement point or the combination of the measurement points may also be used as the characteristic marker. Similarly, a strip shape or a right-angle shape may be used as the characteristic marker. FIG. 3 is schematic diagram of a characteristic marker according to an embodiment of the disclosure. In an embodiment, when the characteristic marker in the wafer measurement region image fails to be identified, it is prompted that a wafer measurement region deviates. That is, if the characteristic marker cannot be identified during identification of the wafer measurement region image, a prompt is sent.

In S106, the actual position of the characteristic marker in the wafer measurement region image is determined.

Referring to FIG. 2, in S106, in an embodiment, the operation that determining an actual position of the characteristic marker 201 in the wafer measurement region image 200 includes: determining the central coordinate (m′, n′) of the characteristic marker 201 in the wafer measurement region image 200.

In S108, the deviation amount of the characteristic marker is determined according to the actual position of the characteristic marker and the standard position of the characteristic marker.

In an embodiment, the characteristic marker in the wafer measurement region image and the corresponding standard characteristic marker in the layout are converted into the same coordinate system.

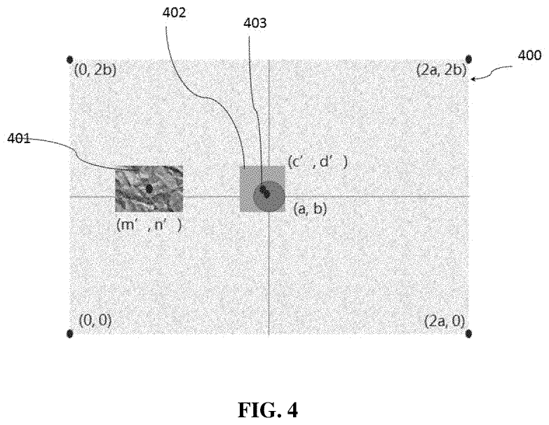

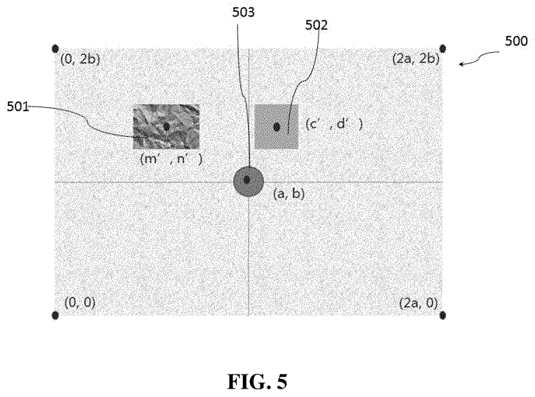

Referring to FIG. 2, in S108, in an embodiment, the operation that comparing the coordinate (m′, n′) of the actual position of the characteristic marker 201 with coordinate (m, n) of a standard position of the characteristic marker 201 to determine the deviation amount of the characteristic marker includes: comparing the central coordinate (m′, n′) of the characteristic marker 201 in the wafer measurement region image 200 with the central coordinate (m, n) of the standard characteristic marker to obtain a deviation amount of the central coordinate of the characteristic marker 201 in the wafer measurement region image 200. FIG. 2 illustrates a wafer measurement region image in an ideal state. (m′, n′) coincide with (m, n). However, (m′, n′) in actual measurement have a certain deviation amount relative to (m, n), as shown in FIG. 4 and FIG. 5 below. In an embodiment, the actual position of the characteristic marker in the wafer measurement region image includes the central coordinate of the actual position of the characteristic marker in the wafer measurement region image, and the standard position includes the central coordinate of the standard position. In an embodiment, the deviation amount of the actual position of the characteristic marker in the wafer measurement region image from the standard position is a deviation amount of the central coordinate of the actual position of the characteristic marker in the wafer measurement region image from the central coordinate of the standard position.

In S110, the deviation amount of the measurement point in the wafer measurement region image is determined according to the deviation amount of the characteristic marker.

Referring to FIG. 2, in S110, in an embodiment, a deviation amount of the measurement point 202 in the wafer measurement region image 200 is predicted according to the relative position between the standard position (m, n) of the standard characteristic marker in the layout and the measurement point (c, d) in the layout, and according to a deviation amount of the characteristic marker 201. That is, since the relative position of the characteristic marker and the measurement point is fixed in the layout, during actual measurement, the deviation amount of the characteristic marker 201 may be equivalent to the deviation amount of the measurement point.

In an embodiment, a preset range of the deviation amount is set according to sizes of the measurement point and a machine measurement spot. In an embodiment, the sizes of the measurement point and the machine measurement spot are fixed. In an embodiment, the size of the measurement point is a length or a width of the measurement point, and the size of the measurement spot is a diameter of the measurement spot. In an embodiment, when the deviation amount of the measurement point in the wafer measurement region image is within the preset range, it is prompted that detection has passed or a prompt is not sent.

FIG. 4 is a schematic diagram of a wafer measurement region image 400 according to an embodiment of the disclosure. Referring to FIG. 4, a size of a measurement point 402 and a size of a machine measurement spot 403 are fixed. In an embodiment, the size of the measurement point 402 is 80 μm*80 μm. The machine measurement spot 403 has a diameter of d=60 μm. The central coordinate of the actual position of the characteristic marker is (m′, n′). The central coordinate of the standard position is (m, n). The preset range is m−10≤m′≤m+10, and n−10≤n′≤n+10. Because the relative position of the measurement point 402 and a characteristic marker 401 is fixed, a deviation amount of the coordinate (c, d) of a standard central point of the measurement point 402 from the coordinate (c′, d′) of the central point during actual measurement may be calculated by using the deviation amount of the central coordinate of an actual position of the characteristic marker 401 from the central coordinate of the standard position, to further determine whether the measurement point 402 deviates. A specific determining step is as follows.

If m′=m and n′=n, that is, c′=c=a and d′=d=b, the actual measurement point of the machine is the center of the measurement point that needs to be measured. It indicates that the deviation amount of the measurement point falls within the preset range, as shown in FIG. 2.

If m−10≤m′≤m+10 and n−10≤n′≤n+10, c−10≤c′≤c+10 and d−10≤d′≤d+10, that is, a−10≤c′≤a+10 and b−10≤d′≤b+10. It indicates that in this case, the measurement point has a certain deviation but still falls within the preset range, as shown in FIG. 4.

In an embodiment, when the deviation amount of the measurement point exceeds the preset range, alarm information is outputted or it is prompted that the measurement point deviates.

FIG. 5 is a schematic diagram of a wafer measurement region image 500 according to an embodiment of the disclosure.

Referring to FIG. 5, a size of a measurement point 502 and a size of a machine measurement spot 503 are fixed. In an embodiment, the size of the measurement point 502 is 80 μm*80 μm. The machine measurement spot 503 has a diameter of d=60 μm. The central coordinate of the actual position of the characteristic marker is (m′, n′). The central coordinate of the standard position is (m, n). The preset range is m−10≤m′≤m+10, and n−10≤n′≤n+10. Because the relative position of the measurement point 502 and a characteristic marker 501 is fixed, a deviation amount of the coordinate (c, d) of a standard central point of the measurement point 502 from the coordinate (c′, d′) of the central point during actual measurement may be calculated by using the deviation amount of the central coordinate of an actual position of the characteristic marker 501 from the central coordinate of the standard position, to further determine whether the measurement point 502 deviates. A specific determining step is as follows.

If m′≤m−10 or m′≥m+10 or n′≤n−10 or n′≥n+10, c′≤c−10 or c′≥c+10 or d′≤d−10 or d′≥d+10, that is, c′≤a−10 or c′≥a+10 or d′≤b−10 or d′≥b+10. It indicates that the measurement point has completely exceeded the preset range of measurement, and the machine sends an alarm signal after having detected that the measurement point exceeds the preset range, to prompt a technician to adjust or repair the measuring machine.

In an actual wafer measurement process, the machine usually records a final measurement position in the form of an image. A film thickness measuring machine is used as an example. In an ideal case, the center of the measurement point coincides with the central point of the image, as shown in FIG. 2.

During actual measurement, the size of the measurement point and the size of the machine measurement spot are known. Therefore, during calculation of the size of the measurement point in the image, that is obtained through a final test of the machine, and the size of the machine measurement spot, conversion may be performed by using proportional relationships between a size of the image and actual sizes of the measurement point and a measurement range of the machine, to eventually obtain the size of the measurement point in the image and the size of the machine measurement spot.

The characteristic marker is defined, and the image obtained through measurement is identified. Because the relative position between the characteristic marker and the center of the measurement point is fixed, a change in the central point of the measurement point may be obtained by using a change in a position of a central point of the characteristic marker, to further determine whether the measurement point deviates, as shown in FIG. 4 and FIG. 5.

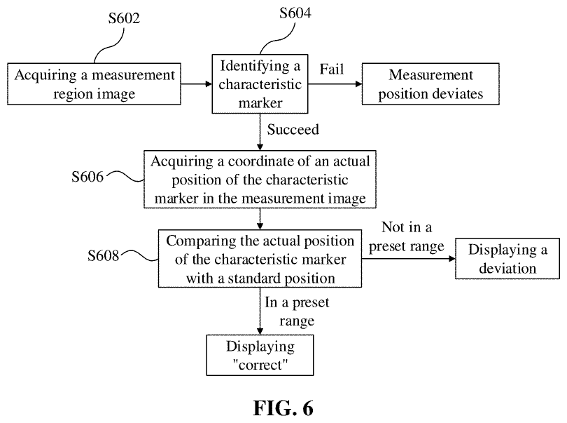

FIG. 6 is a schematic flowchart of wafer measurement according to an embodiment of the disclosure. Details are as follows.

S602: A measurement region image is obtained. A position of a patterned wafer is measured. After the measurement of each position is completed, a real-time measurement image is generated. Measurement images at different positions may be numbered as an image 1, . . . , an image n;

S604: The characteristic marker is identified. The pixel points in the measurement image are identified according to the pixel features of the characteristic marker in a layout. When a pixel feature of a pixel point in the measurement image corresponds to a pixel feature of the characteristic marker in the layout, the pixel feature is retrieved, to obtain an image corresponding to the characteristic marker in the measurement image. If there is no corresponding pixel feature, the identification fails, and it is further determined that a measurement position of the wafer deviates.

S606: A coordinate of an actual position of the characteristic marker in the measurement image is acquired. After the image corresponding to the characteristic marker in the measurement image is obtained, as shown in FIG. 2, the coordinate (m′, n′) of the actual position of the characteristic marker in the measurement image 200 may be directly obtained according to the measurement image 200.

S608: A deviation amount is calculated. The coordinate (m′, n′) of the actual position of the characteristic marker is compared with the coordinate (m, n) of an inputted standard position of the characteristic marker. If the calculated deviation amount is within a preset range, it indicates that the measurement position is correct. Otherwise, it indicates that the measurement position deviates.

The apparatus embodiment of the disclosure is described below, and the apparatus may be configured to perform the foregoing wafer position measurement method of the disclosure.

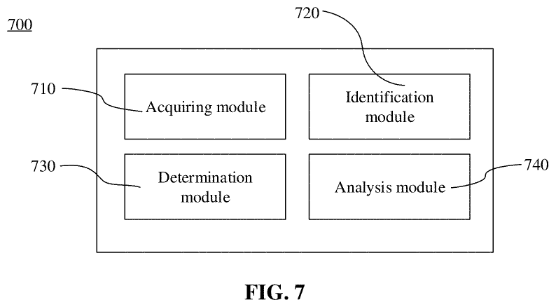

As shown in FIG. 7, a wafer measurement apparatus 700 provided in the embodiments of the disclosure may include:

an acquiring module 710, configured to acquire a wafer measurement region image;

an identification module 720, configured to identify a characteristic marker in the wafer measurement region image;

a determination module 730, configured to determine an actual position of the characteristic marker in the wafer measurement region image; and

an analysis module 740, configured to determine a deviation amount of the characteristic marker according to the actual position of the characteristic marker and a standard position of the characteristic marker, and determine a deviation amount of a measurement point in the wafer measurement region image according to the deviation amount of the characteristic marker.

The functional modules of the wafer measurement apparatus in the exemplary embodiments of the disclosure correspond to the steps in the exemplary embodiments of the foregoing wafer measurement method. Therefore, for details are not disclosed in the apparatus embodiments of the disclosure, reference may be made to the embodiments of the foregoing wafer measurement method of the disclosure.

In the wafer measurement apparatus provided in the embodiments of the disclosure, the deviation amount of the measurement point in the wafer measurement region image is determined by using the deviation amount of the actual position of the characteristic marker from the standard position of the characteristic marker. Through the solution of the disclosure, a deviation problem of a measurement point can be determined and discovered in real time, to facilitate timely adjustment of a measurement position, thereby ensuring the accuracy of a measurement result.

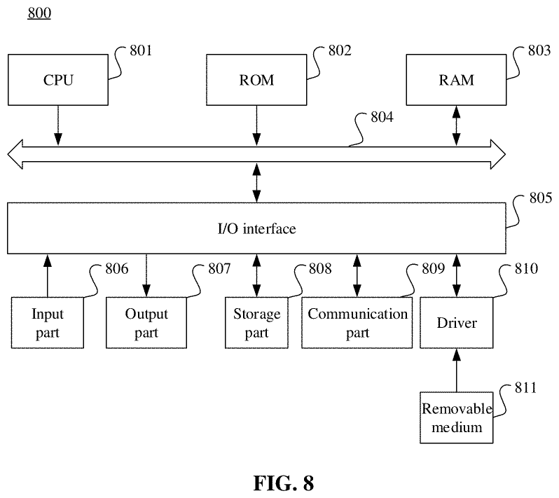

Refer to FIG. 8 below. FIG. 8 is a schematic structural diagram of a computer system 800 of an electronic device which is applicable to implementing the embodiments of the disclosure. The computer system 800 of the electronic device shown in FIG. 8 is only an example, but should not constitute any limitation to the functions and use scope of the embodiments of the disclosure.

As shown in FIG. 8, a computer device 800 includes a central processing unit (CPU) 801. The CPU 801 may perform various appropriate actions and processing according to a program stored in a read-only memory (ROM) 802 or a program loaded into a random access memory (RAM) 803 from a storage part 808. The RAM 803 further stores various programs and data required for the operation of a system. The CPU 801, the ROM 802, and the RAM 803 are connected to each other by a bus 804. An input/output (I/O) interface 805 is also connected to the bus 804.

The following parts that are connected to the I/O interface 805 include an input part 806 such as a keyboard, a mouse, and the like, an output part 807 such as a cathode ray tube (CRT), a liquid crystal display (LCD), a speaker, and the like, the storage part 808 such as a hard disk, and the like, and a communication part 809 of a network interface card such as a LAN card, a modem, and the like. The communication part 809 performs communication via a network such as the Internet. A driver 810 is also connected to the I/O interface 805 as required. A removable medium 811 such as a magnetic disk, an optical disc, a magneto-optical disc, a semiconductor memory, or the like is installed on the driver 810 as required, such that a computer program read from the driver 810 is installed in the storage part 808 as required.

Especially, according to the embodiments of the disclosure, the process described in the foregoing flowcharts may be implemented as a computer software program. For example, the embodiments of the disclosure include a computer program product, including a computer program carried in a computer-readable storage medium. The computer program contains program code used for performing the method as shown in the flowcharts. In the embodiments, the computer program may be downloaded and installed from a network through the communication part 809 and/or installed from the removable medium 811. The computer program is executed by the CPU 801 to perform the foregoing functions defined in the system of this application.

It should be noted that the computer-readable storage medium shown in the disclosure may be a computer-readable signal medium, a computer-readable storage medium or any combination of the foregoing. The computer-readable storage medium may be, for example, but not limited to, an electronic, magnetic, optical, electromagnetic, infrared, or semiconductor system, apparatus or device, or any combination of the foregoing. More specific examples of the computer-readable storage medium may include, but not limited to, the following: an electrical connection having one or more wires, a portable computer disc, a hard disk, a RAM, a ROM, an erasable programmable read-only memory (EPROM or Flash memory), an optical fiber, a portable compact disc read-only memory (CD-ROM), an optical storage device, a magnetic storage device, or any suitable combination of the foregoing. In the disclosure, the computer-readable storage medium may be any tangible medium that contains or stores a program. The program may be used by or in combination with an instruction execution system, apparatus or device. In the disclosure, the computer-readable signal medium may include a propagated data signal with computer-readable program code embodied therein, for example, in baseband or as part of a carrier wave. Such a propagated data signal may take any of a variety of forms, including, but not limited to, an electromagnetic signal, an optical signal, or any suitable combination thereof. The computer-readable signal medium may be any computer-readable storage medium that is not a computer-readable storage medium and can communicate, propagate, or transport a program for use by or in combination with an instruction execution system, apparatus or device. Program code embodied on a computer-readable storage medium may be transmitted using any appropriate medium, including but not limited to wireless, electric wire, optical fiber cable, RF, etc., or any suitable combination of the foregoing.

The flowcharts and block diagrams in the accompanying drawings show the possible architecture, functions, and operations of the system, the method, and the computer program product according to various embodiments of the disclosure. In this regard, each block in the flowcharts or block diagrams can represent a part of a module, a program segment or a code, and the part of the module, the program segment or the code contains one or more executable instructions for implementing the defined logical functions. It should also be noted that in some embodiments as alternatives, the functions labeled in the blocks can occur in an order different from the order labeled in the accompanying drawings. For example, two sequentially shown blocks can be substantially executed in parallel in fact, and they sometimes can also be executed in a reverse order, which is defined by the referred functions. It should also be noted that each block in the block diagrams or the flowcharts and the combination of the blocks in the block diagrams or the flowcharts can be implemented by a dedicated system based on hardware for executing the defined functions or operations, or can be implemented by a combination of the dedicated hardware and computer instructions.

The units described in the embodiments of the disclosure may be implemented in a software fashion or may be implemented in a hardware fashion. The described units may also be disposed in a processor. The names of these units do not constitute a limitation to the units in some cases.

In another aspect, this application further provides a computer-readable storage medium. The computer-readable storage medium may be contained in the electronic device described in the foregoing embodiment or may exist separately without being assembled in the electronic device. The computer-readable storage medium carries one or more programs therein. The foregoing one or more programs, when running on the electronic device, cause the electronic device to implement the wafer measurement method described in the foregoing embodiments.

For example, the electronic device may implement the steps shown in FIG. 1.

It should be noted that although a plurality of modules or units of the device for action execution have been mentioned in the above detailed description, this partition is not compulsory. Actually, according to the embodiments of the disclosure, features and functions of two or more modules or units as described above may be embodied in one module or unit. In contrast, features and functions of one module or unit as described above may be further embodied in more modules or units.

As can be known from the description of the foregoing embodiments, persons skilled in the art may easily understand that the exemplary embodiments described herein may be implemented by using software or software plus necessary hardware. Therefore, the foregoing technical solutions according to the embodiments of the disclosure may be implemented in the form of a software product. The software product may be stored in a non-volatile storage medium (for example, a CD-ROM, a USB disk, or a removable hard disk) or a network, and includes several instructions for instructing a computing device (which may be a personal computer, a server, a touch terminal or a network device) to the methods in the embodiments of the disclosure.

Other embodiments of the disclosure will be easily conceived by those skilled in the art after taking the Description into consideration and practicing the solution disclosed herein. This application is intended to cover any variations, uses, or adaptive changes of the disclosure. These variations, uses, or adaptive changes follow the general principles of the disclosure and include common general knowledge or conventional technical means in the art that are not disclosed herein. The Description and the embodiments are to be regarded as being exemplary only. The true scope and spirit of the disclosure are subject to the following claims.

It will be appreciated that the disclosure is not limited to the exact construction that has been described above and illustrated in the accompanying drawings, and that various modifications and changes can be made without departing from the scope thereof. It is intended that the scope of the invention only be limited by the appended claims.

1. A method for wafer measurement, applicable to a patterned wafer, comprising:
acquiring a wafer measurement region image;
identifying a characteristic marker in the wafer measurement region image;
determining an actual position of the characteristic marker in the wafer measurement region image;
determining a deviation amount of the characteristic marker according to the actual position of the characteristic marker and a standard position of the characteristic marker; and
determining a deviation amount of a measurement point in the wafer measurement region image according to the deviation amount of the characteristic marker.

2. The method according to claim 1, wherein a feature of the characteristic marker in the wafer measurement region image is unique.

3. The method according to claim 1, wherein the standard position of the characteristic marker in the wafer measurement region image is determined according to a position of the characteristic marker in a layout corresponding to the wafer measurement region image.

4. The method according to claim 3, wherein the deviation amount of the characteristic marker is calculated according to the actual position of the characteristic marker in the wafer measurement region image and the standard position.

5. The method according to claim 1, wherein the actual position of the characteristic marker in the wafer measurement region image comprises a central coordinate of the actual position of the characteristic marker in the wafer measurement region image, and the standard position of the characteristic marker comprises a central coordinate of the standard position of the characteristic marker.

6. The method according to claim 5, wherein the deviation amount of the actual position of the characteristic marker in the wafer measurement region image from the standard position is a deviation amount of the central coordinate of the actual position of the characteristic marker in the wafer measurement region image from the central coordinate of the standard position.

7. The method according to claim 1, further comprising:
prompting that the measurement point deviates when the characteristic marker in the wafer measurement region image fails to be identified.

8. The method according to claim 1, further comprising: setting a preset range of the deviation amount according to sizes of the measurement point and a machine measurement spot.

9. The method according to claim 8, wherein the sizes of the measurement point and the machine measurement spot are fixed.

10. The method according to claim 9, wherein the size of the measurement point is a length or a width of the measurement point, and the size of the machine measurement spot is a diameter of the machine measurement spot.

11. The method according to claim 8, wherein when the deviation amount of the measurement point is within the preset range, no prompt is sent or it is prompted that the measurement point does not deviate.

12. The method according to claim 8, wherein when the deviation amount of the measurement point exceeds the preset range, alarm information is outputted or it is prompted that the measurement point deviates.

13. An apparatus for wafer measurement, comprising:
one or more processors; and
a storage apparatus, configured to store one or more programs, wherein the one or more programs, when executed by the one or more processors, cause the one or more processors to execute operations of:
acquiring a wafer measurement region image;
identifying a characteristic marker in the wafer measurement region image;
determining an actual position of the characteristic marker in the wafer measurement region image; and
determining a deviation amount of the characteristic marker according to the actual position of the characteristic marker and a standard position of the characteristic marker, and determining a deviation amount of a measurement point in the wafer measurement region image according to the deviation amount of the characteristic marker.

14. The apparatus according to claim 13, wherein a feature of the characteristic marker in the wafer measurement region image is unique.

15. The apparatus according to claim 13, wherein the standard position of the characteristic marker in the wafer measurement region image is determined according to a position of the characteristic marker in a layout corresponding to the wafer measurement region image.

16. The apparatus according to claim 15, wherein the deviation amount of the characteristic marker is calculated according to the actual position of the characteristic marker in the wafer measurement region image and the standard position.

17. The apparatus according to claim 13, wherein the actual position of the characteristic marker in the wafer measurement region image comprises a central coordinate of the actual position of the characteristic marker in the wafer measurement region image, and the standard position of the characteristic marker comprises a central coordinate of the standard position of the characteristic marker.

18. The apparatus according to claim 17, wherein the deviation amount of the actual position of the characteristic marker in the wafer measurement region image from the standard position is a deviation amount of the central coordinate of the actual position of the characteristic marker in the wafer measurement region image from the central coordinate of the standard position.

19. The apparatus according to claim 13, wherein the one or more processors further execute operation of:
prompting that the measurement point deviates when the characteristic marker in the wafer measurement region image fails to be identified.

20. A computer-readable storage medium, having stored thereon a computer program, wherein the computer program, when executed by a processor, implements the method according to claim 1.
